(19) United States
(12) Patent Application Publication
(10) Pub. No.: US 2007/0125416 A1
(43) Pub. Date: Jun. 7, 2007

(54) THERMOELECTRIC MATERIAL AND THERMOELECTRIC CONVERSION DEVICE USING SAME

(75) Inventors: Naokazu Iwanade, Itabashi-Ku (JP); Naruhito Kondo, Kawasaki-Shi (JP); Osamu Tsuneoka, Setagaya-Ku (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/567,366

(22) Filed: Dec. 6, 2006

(30) Foreign Application Priority Data
Dec. 7, 2005 (JP) 2005-353969
Dec. 7, 2005 (JP) 2005-353970

(51) Int. Cl. H01L 35/12

(52) U.S. Cl. 136/236.1

(57) ABSTRACT

The thermoelectric material is represented by the following composition formula of (Tiₐ₁Zr_{b1}Hf_{c1})ₓA_{y}B_{100-x-y}, in which element A is at least one element selected from the group consisting of Ni and Co, element B is at least one element selected from the group consisting of Sn and Sb, 0≦a1≦1, 0≦b1≦1, 0≦c1≦1, and a1+b1+c1=1 hold, and 30≦x≦35 and 30≦y≦35 hold, and the thermoelectric material comprises a phase having an MgAgAs type crystal structure as a major phase. In this thermoelectric material, the density of the thermoelectric material is more than 99.0% of the true density. When this thermoelectric material is used for either one or both of p-type elements and n-type elements, a thermoelectric conversion device having high thermoelectric conversion performance is realized.

### BACKGROUND OF THE INVENTION

1. Field of the Invention

The present invention relates to a thermoelectric material having a thermoelectric effect, particularly, using a half Heusler compound and also relates to a thermoelectric conversion device using the thermoelectric material.

2. Related Art

In recent years, concomitant with an increase in consciousness about global environmental issues, thermoelectric cooling devices using the Peltier effect, which are flon-less cooling devices, have increasingly drawn attention. In addition, in order to decrease the amount of exhaust carbon dioxide in consideration of global warming, thermoelectric generation devices directly converting unused exhaust heat energy to electric energy have also started to draw attention.

Incidentally, performance index Z of a thermoelectric material can be represented by the following formula (1).
Z=α²·σ/κ(=Pf/κ) (1)

In the above formula (1), α indicates the Seebeck coefficient of the thermoelectric material, σ indicates electrical conductivity, and κ indicates thermal conductivity. The reciprocal number of the electrical conductivity σ can be represented by electrical resistivity ρ. In addition, the term α²·σ is called output factor Pf. Z has a dimension inverse to temperature, and hence, ZT obtained by multiplying the performance index Z by absolute temperature T is a dimensionless number.

This ZT value is called a dimensionless performance index. The ZT value has a relationship with thermoelectric conversion efficiency of a thermoelectric material, and a material having a larger ZT value has higher thermoelectric conversion efficiency.

As shown in the formula (1), the thermoelectric material is required to have a higher Seebeck coefficient α and a lower electrical resistivity ρ, that is, a higher output factor Pf, and a lower thermal conductivity κ.

Since some intermetallic compounds having an MgAgAs type crystal structure have semiconductor properties, they have drawn attention as a novel thermoelectric material.

A half Heusler compound is one of the intermetallic compounds which have an MgAgAs type crystal structure and which exhibit semiconductor properties.

The half Heusler compound is a cubic crystal compound in which harmful materials are not contained at all or the content thereof is decreased as small as possible. When constituent elements of the half Heusler compound are represented by M, A, and B, the structure thereof is observed such that the element A is inserted in a NaCl type crystal lattice formed of the elements M and B. Since having a high Seebeck coefficient at room temperature, the half Heusler compound having the structure described above has drawn attention in recent years in view of global environmental issues.

It has been reported that the thermoelectric properties of the half Heusler compound depend on the combination of constituent elements (for example, see Japanese Unexamined Patent Application Publication No. 2001-189495).

For example, it has been reported that ZrNiSn has a high Seebeck coefficient, such as −176 μV/K, at room temperature (for example, see J. Phys.: Condensed Matter 11, 1697-1709 (1999)). However, since ZrNiSn has a high resistivity, such as 11 mΩ·cm, at room temperature, and also has a high thermal conductivity, such as 8.8 w/mK, the dimensionless performance index ZT is low, such as 0.01.

On the other hand, it has been reported that HoPdSb, a thermoelectric material containing a rare earth element, has a slightly low thermal conductivity, such as 6 W/mK, as compared to that of ZrNiSn (for example, see Appl. Phys. Lett. 74, 1415 to 1417 (1999)). However, since HoPdSb has a slightly low Seebeck coefficient, such as 150 μV/K, at room temperature and has a high resistivity, such as 9 mΩ·cm, the dimensionless performance index ZT thereof still remains low, such as 0.01. In addition, it has also been reported that Ho_{0.5}Er_{0.5}PdSb_{1.05}, Er_{0.25}Dy_{0.75}Pd_{1.02}Sb, and Er_{0.25}Dy_{0.75}PdSb_{1.05} have low dimensionless performance indexes, such as 0.04, 0.03, and 0.02, respectively, at room temperature.

Heretofore, it has been known that the thermoelectric properties of a half Heusler compound vary depending on combination of constituent elements.

However, a related half Heusler compound has not exhibited sufficiently high thermoelectric properties as of today.

Development of a thermoelectric material having excellent thermoelectric properties, which is formed using a half Heusler compound in which harmful materials are not contained at all or the content thereof is decreased as small as possible, has been desired.

Incidentally, in the known art, generally, the thermoelectric conversion device using the Peltier effect or the Seebeck effect is formed of p-type elements containing a p-type thermoelectric conversion material and n-type elements containing an n-type thermoelectric conversion material, which are alternately connected to each other in series.

As a thermoelectric conversion material which is presently used at approximately room temperature, a single-crystal or a polycrystalline Bi—Te-based compound is frequently used because of its high efficiency. In addition, as a thermoelectric conversion material which is used at a temperature higher than room temperature, also because of its high efficiency, a Pb—Te-based compound is used.

However, Se (selenium), which is used as a dopant for a Bi—Te-based compound, and Pb (lead) are harmful and toxic to the human body and are also unfavorable in view of global environmental issues.

Heretofore, as one of thermoelectric conversion materials in which harmful substances are not contained at all or the content thereof is decreased as small as possible, for example, a half Heusler-based thermoelectric conversion material having an MgAgAs type crystal phase may be mentioned (for example, see J. Phys.: Condensed Matter 11, 1697 to 1709 (1999) and Proc. 18th International Conference on Thermoelectrics, 344 to 347 (1999)).

In a related half Heusler-based thermoelectric conversion material, the amount of harmful substances used therefor is suppressed as small as possible.

However, the thermoelectric conversion properties of a related half Heusler-based thermoelectric conversion material have not reached to a level equivalent to that of a Bi—Te-based material.

Accordingly, instead of Bi—Te-based and Pb—Te-based materials, a thermoelectric conversion material, which has no harmful and toxic properties and high thermoelectric conversion properties, has been desired.

### SUMMARY OF THE INVENTION

The present invention has been conceived in consideration of the above circumstances, and an object of the present invention is to provide a thermoelectric material and a thermoelectric conversion device using this thermoelectric material, the thermoelectric material being formed using a half Heusler compound exhibiting a higher dimensionless performance index ZT which is obtained by increasing the output factor to a relatively high level and sufficiently decreasing the thermal conductivity.

Another object of the present invention is to also provide a non-harmful and non-toxic thermoelectric conversion material having high thermoelectric conversion properties and a thermoelectric conversion device using this thermoelectric conversion material.

These and other objects can be achieved according to the present invention by providing, in one aspect, a thermoelectric material which is represented by following composition formula of (Tiₐ₁Zr_{b1}Hf_{c1})ₓA_{y}B_{100-x-y}, in which element A is at least one element selected from the group consisting of Ni and Co, element B is at least one element selected from the group consisting of Sn and Sb, 0≦a1≦1, 0≦b1≦1, 0≦c1≦1, and a1+b1+c1=1 hold and 30≦x≦35 and 30≦y≦35 hold, and which comprises a phase having an MgAgAs type crystal structure as a major phase, wherein density of the thermoelectric material is more than 99.0% of true density.

In another aspect, there is also provided a thermoelectric material which is represented by the following composition formula of (Ln_{d}(Tiₐ₂Zr_{b2}Hf_{c2})_{1-d})ₓA_{y}B_{100-x-y}, in which element Ln is at least one element selected from the group consisting of Y and rare earth elements, element A is at least one element selected from the group consisting of Ni and Co, element B is at least one element selected from the group consisting of Sn and Sb, 0≦a2≦1, 0≦b2≦1, 0≦c2≦1, and a2+b2+c2=1 hold, 0<d≦0.3 holds and 30≦x≦35 and 30≦y≦35 hold, and which comprises a phase having an MgAgAs type crystal structure as a major phase, wherein the density of the thermoelectric material is more than 99.0% of the true density.

In a further aspect, there is also provided a thermoelectric conversion material which is represented by the following composition formula of (Tiₐ₁Zr_{b1}Hf_{c1})ₓNi_{y}Sn_{100-x-y})₁₋ₚAₚ, in which element A is at least one element selected from the group consisting of C, N, and O, 0<a1<1, 0<b1<1, 0<c1<1, and a1+b1+c1=1 hold, 30≦x≦35 and 30≦y≦35 hold, and 0.05<p<0.1 holds, and which comprises a phase having an MgAgAs type crystal structure as a major phase.

In a still further aspect, there is provided a thermoelectric conversion material which is represented by the following composition formula of ((Ln_{d}(Tiₐ₂Zr_{b2}Hf_{c2})_{1-d})ₓNi_{y}Sn_{100-x-y})₁₋ₚAₚ, in which element A is at least one element selected from the group consisting of C, N, and O, element Ln is at least one element selected from the group consisting of Y and rare earth elements, 0≦a2≦1, 0≦b2≦1, 0≦c2≦1, and a2+b2+c2=1 hold, 0<d≦0.3 holds, 30≦x≦35 and 30≦y≦35 hold, and 0.05<p<0.1 holds, and which comprises a phase having an MgAgAs type crystal structure as a major phase.

In preferred embodiments of the above aspects, at least one of the Ti, Zr and Hf may be partly replaced with at least one element selected from the group consisting of V, Nb, Ta, Cr, Mo and W. The element A may be partly replaced with at least one element selected from the group consisting of Mn, Fe and Cu. The element B may be partly replaced with at least one element selected from the group consisting of Si, Mg, As, Bi, Ge, Pb, Ga and In.

In a still further aspect of the present invention, the above objects can be achieved by providing a thermoelectric conversion device comprising:

at least one p-type element including a p-type thermoelectric material; and

at least one n-type element including an n-type thermoelectric material, the p-type element and the n-type element being alternately connected to each other in series,

wherein at least one of the p-type thermoelectric material and the n-type thermoelectric material is represented by the following composition formula of (Tiₐ₁Zr_{b1}Hf_{c1})ₓA_{y}B_{100-x-y}, in which element A is at least one element selected from the group consisting of Ni and Co, element B is at least one element selected from the group consisting of Sn and Sb, 0≦a1≦1, 0≦b1≦1, 0≦c1≦1, and a1+b1+c1=1 hold and 30≦x≦35 and 30≦y≦35 hold, and at least one of the p-type and n-type thermoelectric materials comprises a phase having an MgAgAs type crystal structure as a major phase, wherein density of the thermoelectric material is more than 99.0% of true density.

In anther aspect, there is also provided a thermoelectric conversion device comprising:

at least one p-type element including a p-type thermoelectric material; and

at least one n-type element including an n-type thermoelectric material, the p-type element and the n-type element being alternately connected to each other in series,

wherein at least one of the p-type thermoelectric material and the n-type thermoelectric material is represented by the following composition formula of (Ln_{d}(Tiₐ₂Zr_{b2}Hf_{c2})_{1-d})ₓA_{y}B_{100-x-y}, in which element Ln is at least one element selected from the group consisting of Y and rare earth elements, element A is at least one element selected from the group consisting of Ni and Co, element B is at least one element selected from the group consisting of Sn and Sb, 0≦a2≦1, 0≦b2≦1, 0≦c2≦1, and a2+b2+c2=1 hold, 0<d≦0.3 holds and 30≦x≦35 and 30≦y≦35 hold, and at least one of the p-type and n-type thermoelectric materials comprises a phase having an MgAgAs type crystal structure as a major phase, wherein density of the thermoelectric material is more than 99.0% of true density.

In a further aspect, there is also provided a thermoelectric conversion device comprising:

at least one p-type element including a p-type thermoelectric conversion material; and

at least one n-type element including an n-type thermoelectric conversion material, the p-type element and the n-type element being alternately connected to each other in series,

wherein at least one of the p-type thermoelectric conversion material and the n-type thermoelectric conversion material is represented by the following composition formula of (Tiₐ₁Zr_{b1}Hf_{c1})ₓNi_{y}Sn_{100-x-y}, in which element A is at least one element selected from the group consisting of C, N, and O, 0<a1<1, 0<b1<1, 0<c1<1, and a1+b1+c1=1 hold, 30≦x≦35 and 30≦y≦35 hold, and 0.05<p<0.1 holds, and at least one of the p-type and n-type thermoelectric materials comprises a phase having an MgAgAs type crystal structure as a major phase.

In a still further aspect, there is also provided a thermoelectric conversion device comprising:

at least one p-type element including a p-type thermoelectric conversion material; and

at least one n-type element including an n-type thermoelectric conversion material, the p-type element and the n-type element being alternately connected to each other in series,

wherein at least one of the p-type thermoelectric conversion material and the n-type thermoelectric conversion material is represented by the following composition formula of ((Ln_{d}(Tiₐ₂Zr_{b2}Hf_{c2})_{1-d})ₓNi_{y}Sn_{100-x-y})₁₋ₚAₚ, in which element A is at least one element selected from the group consisting of C, N, and O, element Ln is at least one element selected from the group consisting of Y and rare earth elements, 0≦a2≦1, 0≦b2≦1, 0≦c2≦1, and a2+b2+c2=1 hold, 0<d≦0.3 holds, 30≦x≦35 and 30≦y≦35 hold, and 0.05<p<0.1 holds, and at least one of the p-type and n-type thermoelectric materials comprises a phase having an MgAgAs type crystal structure as a major phase.

In preferred embodiments of the above aspects, at least one of the Ti, Zr and Hf may be partly replaced with at least one element selected from the group consisting of V, Nb, Ta, Cr, Mo and W. The element A may be partly replaced with at least one element selected from the group consisting of Mn, Fe and Cu. The element B may be partly replaced with at least one element selected from the group consisting of Si, Mg, As, Bi, Ge, Pb, Ga and In.

According to the thermoelectric material of the present invention and the thermoelectric conversion device using this material of the characters and structures mentioned above, the thermoelectric material can exhibit a high dimensionless performance index ZT by a relatively high output factor and a sufficiently low thermal conductivity, and harmful materials are not contained at all or the content thereof is decreased as small as possible. In addition, by using such thermoelectric material, a high performance thermoelectric conversion device and thermoelectric conversion module can be easily manufactured, and hence, the present invention can be used very advantageously in industrial fields.

Furthermore, according to the present invention of the characters further mentioned above, the thermoelectric conversion material, the thermoelectric conversion device and a thermoelectric conversion module are non-harmful and non-toxic and have high performance, and hence, the present invention can be used very advantageously in industrial fields.

The nature and further characteristic features of the present invention will be made clearer from the following descriptions made with reference to preferred embodiments and examples.

### BRIEF DESCRIPTION OF THE DRAWINGS

In the accompanying drawings:

FIG. 1 is a schematic cross-sectional view showing the structure of a thermoelectric conversion device according to the present invention;

FIG. 2 is a graph showing the relationship between a sintering temperature of a thermoelectric material of example 1 and the percentage of density/true density; and

FIG. 3 is an enlarged view showing one pair of a p-type semiconductor and an n-type semiconductor, the pair being included in the thermoelectric conversion device shown in FIG. 1.

### DESCRIPTION OF THE PREFERRED EMBODIMENTS

A thermoelectric material of a first embodiment in one aspect according to the present invention will be described hereunder.

First of all, definition of terms used in the present invention will be described.

In the present invention, the major phase indicates a crystal phase having a largest volume fraction among crystal phases forming the thermoelectric material.

In addition, in the present invention, the true density indicates a density obtained by actual measurement of the volume and the weight of a sample of a thermoelectric material formed by melting in which no void is present at all.

As can be seen from the formula (1) (Z=α²·σ/κ(=Pf/κ)), the thermoelectric materials exhibits a higher dimensionless performance index ZT and more excellent performance as the output factor Pf is increased and the thermal conductivity κ is decreased. The output factor Pf of the thermoelectric material and the thermal conductivity κ thereof depend, for example, on constituent elements, a crystal structure and a texture conformation.

The inventors of the present invention discovered that when the density of an intermetallic compound having an MgAgAs type crystal structure is made to be close to the true density, the output factor Pf (=α2/ρ), the Seebeck coefficient, and the conductivity are improved, and a high performance index can be obtained as compared to the case in which the material density is low.

That is, the thermoelectric material according to the first embodiment is a half Heusler compound having an MgAgAs type crystal structure as a major phase, as represented by the following composition formula (2), and the density of the thermoelectric material is more than 99.0% of the true density.
(Tiₐ₁Zr_{b1}Hf_{c1})ₓA_{y}B_{100-x-y} (2)

In the above composition formula (2), element A is at least one element selected from the group consisting of Ni and Co; element B is at least one element selected from the group consisting of Sn and Sb; 0≦a1≦1, 0≦b1≦1, 0≦c1≦1, and a1+b1+c1=1 hold; and 30≦x≦35 and 30≦y≦35 hold.

In the thermoelectric material represented by the composition formula (2), when the constituent elements are represented by M, A, and B, at least one of Ti, Zn, and Hf is used as an element at the M site. The thermal conductivity κ can be decreased by these elements.

In addition, when at least two elements among Ti, Zn, and Hf are used as the elements at the M site, dispersion of phonons can be made to occur due to non-uniformity in atomic radius and atomic weight, and as a result, the thermal conductivity κ can be significantly decreased.

Furthermore, the inventors of the present invention discovered that in the thermoelectric material represented by the composition formula (2), when Ti, Zr, and Hf are all used as the elements at the M site, the Seebeck coefficient α is effectively increased. It is believed that, in a thermoelectric material containing all Ti, Zr, and Hf among the thermoelectric materials represented by the composition formula (2), a steep change in electron density distribution in the vicinity of the Fermi surface occurs.

When a crystal phase other than the MgAgAs crystal phase is precipitated, the Seebeck coefficient α may be decreased in some cases. Hence, the composition x of the element M and the composition y of the element A are preferably set to be 30≦x≦35 and 30≦y≦35, respectively. In addition, the composition x of the element M and the composition y of the element A are more preferably set to be 33≦x≦34 and 33≦y≦34, respectively.

In addition, the thermoelectric material represented by the composition formula (2) is a half Heusler compound having an MgAgAs type crystal phase as the major phase and is prepared so that the density exceeds 99.0% of the true density. Hence, compared to a general half Heusler compound, the thermoelectric material represented by the composition formula (2) has a sufficiently low thermal conductivity κ besides a relatively high conventional output factor Pf. As a result, the thermoelectric material represented by the composition formula (2) can have a high dimensionless performance index ZT.

Next, a thermoelectric material of a second embodiment according to the present invention will be described.

That is, the thermoelectric material according to the second embodiment is a half Heusler compound having an MgAgAs type crystal structure as a major phase, as represented by the following composition formula (3), and the density of the thermoelectric material is more than 99.0% of the true density.
(Ln_{d}(Tiₐ₂Zr_{b2}Hf_{c2})_{1-d})ₓA_{y}B_{100-x-y} (3)

In the above composition formula (3), Ln is at least one element selected from the group consisting of Y and rare earth elements; A is at least one element selected from the group consisting of Ni and Co; B is at least one element selected from the group consisting of Sn and Sb; 0≦a2≦1, 0≦b2≦1, 0≦c2≦1, and a2+b2+c2=1 hold; 0<d≦0.3 holds; and 30≦x≦35 and 30≦y≦35 hold.

The inventors of the present invention discovered that when the element M of the half Heusler compound MAB (M=Ti, Zr, and Hf) represented by the composition formula (2) is partly replaced with at least one element selected from the group consisting of Y and rare earth elements, which have an atomic radius larger than any of Ti, Zr, and Hf, the thermal conductivity κ can be improved.

That is, it was discovered that the element Ln (at least one element selected from the group consisting of Y and rare earth elements) is an effective element to decrease the thermal conductivity κ.

As the element Ln, rare earth elements from La having an atomic number of 57 to Lu having an atomic number of 71 in the periodic table are all included. In consideration of the melting point and the atomic radius, Er, Gd, and Nd are particularly preferable as the element Ln.

The effect of decreasing this thermal conductivity κ can be obtained even by a small amount of Ln. However, in order to further decrease the thermal conductivity κ, the composition ratio of Ln to the total of Ln and M (Ti, Zr, and Hf) is preferably set to 0.1 atomic percent or more. When the composition ratio of Ln is more than 30 atomic percent, a crystal phase other than the MgAgAs type crystal phase, such as an LnSn₃ phase, apparently precipitates, and as a result, the Seebeck coefficient α may be decreased in some cases.

Hence, d is preferably set to be 0<d≦0.3, and more preferably set to be 0.001≦d≦0.3.

In the thermoelectric material represented by the composition formula (3), as is the case of that represented by the composition formula (2), x and y are preferably set to be 30≦x≦35 and 30≦y≦35, respectively. The reason for this is that when x and y are out of the ranges described above, a crystal phase other than the MgAgAs type crystal precipitates, and as a result, the Seebeck coefficient α may be decreased in some cases.

In general, in a half Heusler compound, when the total number of valence electrons is approximately 18, a high Seebeck coefficient can be observed. For example, the outer-shell electron arrangement of ZrNiSn is represented by Zr(5d²6s²), Ni(3d⁸4s²), and Sn(5s²5p²), and the total number of valence electrons is 18. The total number of valence electrons of TiNiSn and HfNiSn also is 18 as is the case described above.

On the other hand, as shown by the composition formula (3), when the element M (Ti, Zr, and Hf) is partly replaced with a rare earth element, the total number of valence electrons of a half Heusler compound containing a rare earth element (except Ce, Eu, and Yb), which has an outer-shell electron arrangement represented by (5d¹6s²), may be deviated from 18 in some cases.

However, this deviation of the total number of valence electrons can be corrected by appropriate adjustment of x and y.

In the composition formulas (2) and (3), the element M (Ti, Zr, and Hf) may be partly replaced with at least one element M′ selected from the group consisting of V, Nb, Ta, Cr, Mo, and W. The element M′ may be used alone or in combination.

When the element M is partly replaced with the element M′, the total number of valence electrons of the MgAgAs type crystal phase, which is the major phase, can be adjusted, and hence the Seebeck coefficient α may be increased and/or the resistivity ρ may be decreased.

In addition, when this element M′ is used together with a rare earth element so that the total number of valence electrons is controlled to be approximately 18, the Seebeck coefficient α can be increased.

However, the amount of the element M′ used for the replacement is preferably set to 30 atomic percent or less of the element M (Ti, Zr, and Hf). When the amount of the element M′ for the replacement is more than 30 atomic percent, a crystal phase other than the MgAgAs type crystal phase precipitates, and as a result, the Seebeck coefficient α may be decreased in some cases.

In the composition formulas (2) and (3), the element A (Ni and Co) may be partly replaced with at least one element A′ selected from the group consisting of Mn, Fe, Co, and Cu. The element A′ may be used alone or in combination.

When the element A is partly replaced with the element A′, for example, the total number of valence electrons of the MgAgAs type crystal phase, which is the major phase, can be adjusted, and hence, the Seebeck coefficient α may be increased and/or the resistivity ρ may be decreased.

However, the amount of the element A′ used for the replacement is preferably set to 50 atomic percent or less of the element A. In particular, in the case in which the element A is partly replaced with Cu, when the amount of Cu is excessive, the growth of the MgAgAs type crystal may be inhibited in some cases, and hence, the amount of Cu used for the replacement is more preferably set to 30 atomic percent or less.

In the composition formulas (2) and (3), the element B (Sn and Sb) may be partly replaced with at least one element B′ selected from the group consisting of Si, Mg, As, Bi, Ge, Pb, Ga, and In. The element B′ may be used alone or in combination.

When the element B is partly replaced with the element B′, for example, the total number of valence electrons of the MgAgAs type crystal phase, which is the major phase, can be adjusted, and hence, the Seebeck coefficient α may be increased and/or the resistivity ρ may be decreased.

However, in consideration of harmfulness, toxicity, and material cost, the element B′ is more preferably selected from Si and Bi. In addition, the amount of the element B′ used for the replacement is preferably set to 30 atomic percent or less of the element B. When the amount of the element B′ used for the replacement is more than 30 atomic percent, a crystal phase other than the MgAgAs type crystal phase precipitates, and as a result, the Seebeck coefficient α may be decreased in some cases.

Next, a method for producing the thermoelectric material according to the present invention will be described.

First, an alloy containing predetermined amounts of the elements shown in the composition formula (2) or (3) is formed, for example, by means of arc melting or high-frequency melting. When the alloy is formed, a liquid quenching method, such as a single roll method, a twin roll method, a rotary disc method, or a gas atomizing method, may also be used. The liquid quenching method is advantageously used to form fine crystal phases forming an alloy or to expand a solid-solution region of an element inside a crystal phase, and this method also functions to decrease the thermal conductivity κ.

Whenever necessary, heat treatment may be performed for the alloy thus formed. By this heat treatment, since the alloy is formed into a single phase, and the crystal grain diameter is also controlled, the thermoelectric properties can be further improved. In order to prevent oxidation of the alloy, the steps of melting, liquid quenching, heat treatment, and the like are preferably performed in an inert gas atmosphere containing Ar or the like.

Next, after the alloy is pulverized by a ball mill, a brown mill, a stamp mill, or the like, a powdered alloy thus obtained is integrally molded by a sintering method, a hot press method, an SPS method, or the like method. In order to prevent oxidation of the alloy, the integral molding is preferably performed in an inert gas atmosphere containing Ar or the like.

Next, in the thermoelectric material represented by the composition formula (2) or (3), a method for adjusting the density in the range of more than 99.0% of the true density will be described in more detail.

For example, there is described a case in which a thermoelectric material is produced from a powdered alloy by a hot press method at a molding pressure P and a molding temperature T for a predetermined molding time of 1 hour.

In the case described above, when the molding pressure P and the molding temperature T satisfy the following equation (4), the density exceeds 99.0%, and a thermoelectric material having more superior performance can be produced.
P>−0.35T+450 (4)
In the above equation (4), P indicates the molding pressure (MPa) and T indicates the molding temperature (° C.).

On the other hand, when P≦−0.35T+450 holds, the density of the molded body is 99.0% or less. When the density of the molded body is 99.0% or less of the true density, the output factor Pf (=α²/ρ), the Seebeck coefficient α, and the electrical conductivity σ are decreased.

Hence, when the molding pressure P and the molding temperature T are controlled, the density of the thermoelectric material represented by the composition formula (2) or (3) can be adjusted in the range of more than 99.0% of the true density.

The shape and the dimension of the molded body are optionally selected. For example, there may be mentioned a cylindrical shape having an outer diameter of 0.5 to 10 mm and a thickness of 1 to 30 mm or a rectangular parallelepiped shape having a square of 0.5 to 10 mm by 0.5 to 10 mm and a thickness of 1 to 30 mm.

Next, the obtained molded body is machined into a desired shape. The shape and the dimension of the molded body may be optionally selected. For example, there may be mentioned a cylindrical shape having an outer diameter of 0.5 to 10 mm and a thickness of 1 to 30 mm or a rectangular parallelepiped shape having a square of 0.5 to 10 mm by 0.5 to 10 mm and a thickness of 1 to 30 mm.

Next, an embodiment of a thermoelectric conversion device using the thermoelectric material of the present invention will be described.

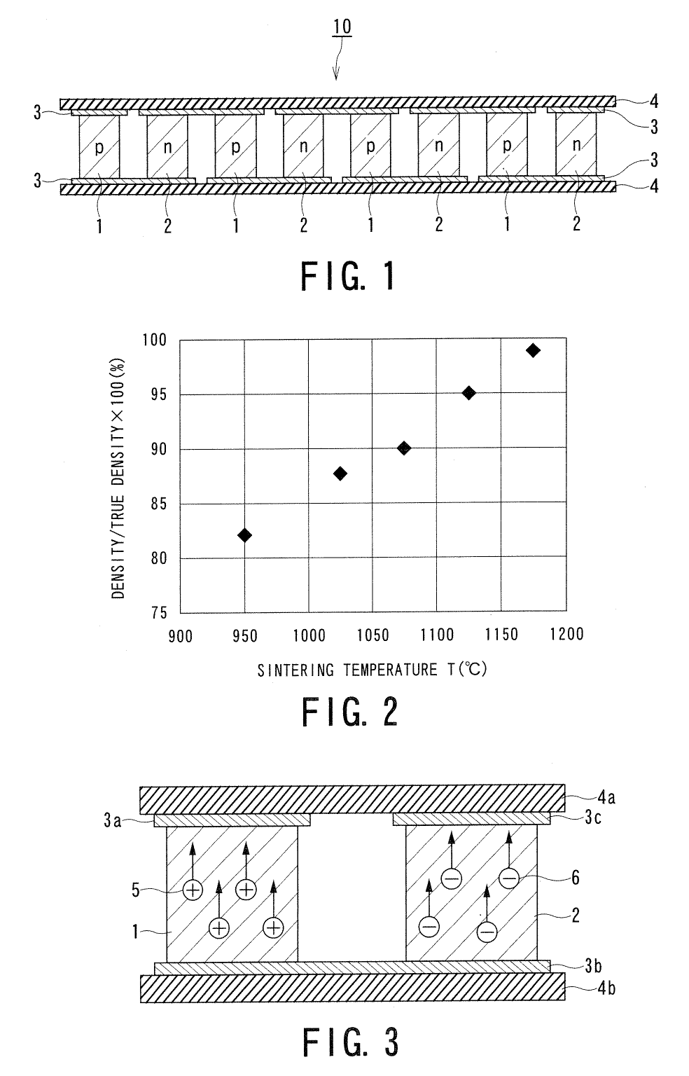

FIG. 1 is a schematic cross-sectional view showing the structure of a thermoelectric conversion device according to the present invention.

A thermoelectric conversion device 10 has the structure which comprises p-type elements 1 each containing a thermoelectric material (p-type thermoelectric material) made of a p-type semiconductor, n-type elements 2 each containing a thermoelectric material (n-type thermoelectric material) made of an n-type semiconductor, electrodes 3 which alternately connects the p-type elements 1 and the n-type elements 2, and insulating substrates 4 covering the electrodes 3.

The p-type elements 1 and the n-type elements 2 are alternately connected to each other via the electrodes 3, so that pn semiconductor pairs are formed.

In this thermoelectric conversion device 10, either one or both of the p-type elements 1 and the n-type elements 2 are formed using the thermoelectric material represented by the composition formula (2) or (3) according to the present invention. When only the p-type elements 1 or the n-type elements 2 are formed using the thermoelectric material according to the present invention, the other type of elements are formed using a Bi—Te-based or a Pb—Te-based thermoelectric material.

Accordingly, since the output factor is increased to a relatively high level, and the thermal conductivity κ is sufficiently decreased, the thermoelectric conversion device 10 can be formed from a thermoelectric material using a half Heusler compound having a higher dimensionless performance index ZT. Hence, as a result, the thermoelectric conversion device 10 has remarkably high performance as compared to that formed from a thermoelectric material using a related half Heusler compound.

### EXAMPLES

The thermoelectric material according to the present invention will be described in detail with reference to examples.

Table 1 shows the results of Example 1 and the results of Comparative Example 1 for comparison purpose.

The Example 1 shown in Table 1 will be described as a representative example. As raw materials, Ti having a purity of 99.9%, Zr having a purity of 99.9%, Hf having a purity of 99.9%, Ni having a purity of 99.99% and Sn having a purity of 99.99% were prepared and were weighed so as to obtain an alloy represented by (Ti_{0.3}Zr_{0.35}Hf_{0.35})NiSn. After the weighed raw materials were mixed together and charged in a water cooling copper-made hearth in an arc furnace, evacuation was performed to a vacuum level of 2×10⁻³ Pa.

Next, a highly pure Ar gas having a purity of 99.999% was introduced at a level of 0.04 MPa to form a reduced-pressure Ar atmosphere, and arc melting was then performed. After the melting, the water cooling copper-made hearth was quenched, so that a metal block was obtained. This metal block was vacuum-sealed in a quartz tube at a high vacuum level of 10⁻⁴ Pa or less and was heat-treated at 1,150° C. for 2 hours. This metal block was then pulverized to a size of 45 μm or less. The powdered alloy thus obtained was molded at a pressure of 50 MPa using a mold having an inside diameter of 20 mm. The molded body thus formed was filled in a carbon-made mold having an inside diameter of 20 mm and was then sintered at 1,200° C. with a pressure of 80 MPa in an Ar atmosphere for 1 hour, so that a disc-shaped sintered body having a diameter of approximately 20 mm was obtained. This sintered body could be regarded as a material which substantially contained no voids.

Next, in order to obtain an accurate density of this sintered body, the outer diameter and the thickness of this sintered body were measured using a micrometer, so that the volume of the sintered body was obtained. From the measurement results, it was found that since the density of the sintered body of this embodiment is 99.9% of the true density, a sintered body having an approximately true density is obtained.

It was confirmed by using a powder x-ray diffraction method that this sintered body is primarily formed of an MgAgAs type crystal phase. It was confirmed that approximately predetermined composition is obtained through an analysis of the composition of this sintered body using an ICP emission spectrometric method.

The thermoelectric properties of the sintered body thus obtained were evaluated by the following methods.

(a) Resistivity ρ

After the sintered body was cut into a sample having a size of 1.5 mm×0.5 mm×18 mm, and electrodes were formed thereon, measurement was performed by a direct current four-terminal method.

(b) Seebeck Coefficient α

After the sintered body was cut into a sample having a size of 5 mm×1.5 mm×0.5 mm, an electromotive force was measure by applying a temperature difference of 2° C. at two ends of the sample, so that the Seebeck coefficient α was obtained.

(c) Thermal Conductivity κ

After the sintered body was cut into a sample having an outer diameter of 10 mm and a thickness of 2.0 mm, a thermal diffusivity was measured using a laser flash method. In addition, the specific heat was obtained by a DSC method. In this measurement, the density of the sintered body which was obtained as described above was used. From the data thus obtained, the thermal conductivity κ (lattice thermal conductivity) was calculated.

By using the resistivity ρ, the Seebeck coefficient α, and the thermal conductivity κ thus obtained, the dimensionless performance index ZT was obtained from the equation (1). The resistivity ρ, the Seebeck coefficient α, the thermal conductivity κ, and the dimensionless performance index ZT at 300K and 700K were as shown below.

| 300K | Resistivity ρ | 8.62 × 10⁻³ Ω · cm | |
|---|---|---|---|
| | Seebeck coefficient α | −333 | μV/K |
| | Thermal conductivity κ | 3.2 | W/mK |
| | ZT | 0.12 | |
| 700K | Resistivity ρ | 2.35 × 10⁻³ Ω · cm | |
| | Seebeck coefficient α | −323 | μV/K |
| | Thermal conductivity κ | 2.6 | W/mK |

| | |
|---|---|
| ZT | 1.20 |

Next, the Comparative Example 1 will be described.

A sintered body was obtained in the same manner as that in example 1 except that the sintering was performed at a temperature of 780° C. and a pressure of 30 MPa in an Ar atmosphere for 1 hour. The density of this sintered body was 69.1% of the true density (Comparative Example 1).

In Table 1, the percentage [(d/do)×100] of the density (d)/the true density (do), the thermal conductivity κ, the output factor Pf, and the dimensionless performance index ZT are shown.

In FIG. 2, the relationship between the percentage of density/true density and a sintering temperature of (Ti_{0.3}Zr_{0.35}Hf_{0.35})NiSn is shown.

As apparent from Table 1, the thermoelectric material (Example 1) having an MgAgAs type crystal phase, the density of which is 99.9% of the true density, has a high dimensionless performance index ZT as compared to that of the thermoelectric material (Comparative Example 1), the density of which is 69.1% of the true density.

TABLE 1

| | | | 300K | | | 700K | | |
|---|---|---|---|---|---|---|---|---|
| | | | κ | Pf | | κ | Pf | |
| | Composition | d/do × 100% | (W/mk) | (mW/mK²) | ZT | (W/mk) | (mW/mK²) | ZT |
| Example 1 | (Ti_{0.3}Zr_{0.35}Hf_{0.35})NiSn | 99.9 | 3.2 | 1.29 | 0.12 | 2.6 | 4.4 | 1.20 |
| comparative | (Ti_{0.3}Zr_{0.35}Hf_{0.35})NiSn | 69.1 | 2.0 | 0.83 | 0.12 | 1.8 | 2.4 | 0.93 |
| example 1 | | | | | | | | |

In a further embodiment of a thermoelectric conversion material according to the present invention will be described with reference to FIGS. 1 and 3.

As also mentioned in the first embodiment mentioned hereinbefore, a performance index Z of a thermoelectric conversion material can be represented by the following formula (1′).
Z=α²/(ρκ) (1′)

In the above formula (1′), α indicates the Seebeck coefficient of the thermoelectric conversion material, ρ indicates electrical resistivity, and κ indicates thermal conductivity. Z has a dimension inverse to temperature, and hence ZT obtained by multiplying the performance index Z by absolute temperature T is a dimensionless number.

This ZT value is called a dimensionless performance index. The ZT value has a relationship with thermoelectric conversion efficiency of a thermoelectric conversion material, and a material having a larger ZT value has higher thermoelectric conversion efficiency.

As shown in the formula (1′), in order to obtain a thermoelectric conversion material having a high ZT value, a higher Seebeck coefficient α, a lower electrical resistivity ρ, and a lower thermal conductivity κ are required.

As one of thermoelectric conversion materials in which harmful substances are not contained at all or the content thereof is decreased as small as possible, the inventors of the present invention have intensively investigated a half Heusler-based material which contains a phase having an MgAgAs type crystal structure (hereinafter referred to as an “MgAgAs type crystal phase”) to improve the performance thereof.

As a result, it was discovered that when a half Heusler-based material is formed which has an MgAgAs type crystal phase as a major phase and which includes at least one element selected from the group consisting of C, N, and O as represented by the following compound formula (2′), a thermoelectric conversion material having a high ZT value can be realized. Hence, as a result, the present invention was made.
((Tiₐ₁Zr_{b1}Hf_{c1})ₓNi_{y}Sn_{100-x-y})₁₋ₚAₚ (2′)

In the above compound formula (2′), element A is at least one element selected from the group consisting of C, N, and O; 0<a1<1, 0<b1<1, 0<c1<1, and a1+b1+c1=1 hold; 30≦x≦35 and 30≦y≦35 hold; and 0.05<p<0.1 holds.

In the present invention, the major phase indicates a phase having a largest volume fraction among all crystal phases and amorphous phases forming the thermoelectric conversion material.

In the thermoelectric conversion material represented by the compound formula (2′), since Ti, Zr and Hf, which are elements of the same group in the periodic table and which are different from each other in atomic mass and atomic radius, are all made to be included, the thermal conductivity κ can be remarkably decreased.

First, the composition ratio p of at least one element selected from the group consisting of C, N and O of the thermoelectric conversion material represented by the compound formula (2′) will be described.

When at least one element selected from the group consisting of C, N and O is included in the thermoelectric conversion material represented by the compound formula (2′), a carbide, a nitride, and/or an oxide is formed, and the volume fraction of the major phase is decreased, and hence, the Seebeck coefficient α is decreased.

On the other hand, since the carbide, the nitride, and/or the oxide precipitates at grain boundaries of the MgAgAs type crystal phase, the thermal conductivity κ is remarkably decreased.

Accordingly, the thermoelectric conversion efficiency is increased to a certain content of the above compound because of this remarkable decrease in the thermal conductivity κ, and in addition, even when the content exceeds the above certain level, such that p>0.05 holds, the thermoelectric conversion efficiency is not seriously decreased.

Since C, N and O are generally liable to be included as impurities during a production process of a thermoelectric conversion material, it is difficult to be accurately controlled at a low composition ratio. In addition, when this control is not performed, the composition ratio p may tend to satisfy p>0.05 in many cases.

Hence, when the composition ratio p of the thermoelectric conversion material represented by the compound formula (2′) is set so as to satisfy 0.05<p, in the thermoelectric conversion material represented by the compound formula (2′), while the effect of decreasing the thermal conductivity κ is obtained by at least one element selected from the group consisting of C, N and O, the productivity can be ensured.

In addition, in consideration of the effect of decreasing the thermal conductivity κ by C, N and O, the composition ratio p is set to be 0.05<p<0.1.

As described below, it is difficult to satisfy p≦0.05.

As a method in which at least one element selected from the group consisting of C, N and O is positively included in a thermoelectric conversion material, for example, there may be mentioned a method in which compounds containing C, N and O (such as ZrC, TiC, TiN, LaN and Sm₂O₃) are added to raw materials, or a method in which heat treatment is performed in an atmosphere of a gas containing C, N and O or a compound gas thereof (such as nitrogen gas, oxygen gas, methane gas, and ammonium gas).

However, in the methods for including the above elements, when the composition ratio p of at least one element selected from the group consisting of C, N and O is controlled at a low level with an upper limit, such that p≦0.05 holds, since the contents of additives or the amounts of gases in an atmosphere must be accurately controlled, the method is very time and labor consuming, and hence, the productivity is degraded.

In addition, as a method in which at least one element selected from the group consisting of C, N and O is positively included in a thermoelectric conversion material, for example, there may be mentioned a method in which some of the above elements is included therein from a crucible material (such as alumina, zirconia, or magnesia) by using a high-frequency induction melting method in which a crucible is used in an alloy melting step.

However, even by this element-including method, when the composition ratio is controlled at a low level with an upper limit, such that p≦0.05 holds, the crucible material must be accurately controlled, and since it is difficult to produce an inexpensive crucible with good productivity, the productivity of the above method is also degraded as that described above.

In addition, as a method in which at least one element selected from the group consisting of C, N and O is positively included in a thermoelectric conversion material, for example, there may be mentioned a method in which the concentrations of C, N and O in an atmospheric gas are controlled, for example, in a melting, a pulverizing, or a sintering step of a manufacturing process.

However, even by this concentration control method, when the composition ratio p is controlled at a low level with an upper limit, such that p≦0.05 holds, after evacuation is performed in the above steps to a high vacuum level, the concentration of an atmospheric gas must be accurately controlled. Hence, large production facilities must be provided, and as a result, the productivity is degraded.

For example, in this concentration control method, when p is set to be p>0.05, without performing evacuation to a high vacuum level, there can be produced a material which has thermoelectric conversion efficiency equivalent to that of a material having a composition ratio p of 0.05 or less, thus decreasing the production cost, as a result.

Hence, in the thermoelectric conversion material represented by the compound formula (2′), in order to obtain the effect of decreasing the thermal conductivity κ using at least one element selected from the group consisting of C, N and O, in view of the productivity, the composition ratio p of at least one element selected from the group consisting of C, N and O is set to be 0.05<p<0.1.

Next, symbols x and y in the thermoelectric conversion material represented by the compound formula (2′) will be described.

When a large amount of a crystal phase other than the MgAgAs type crystal phase is precipitated, the Seebeck coefficient α may be decreased in some cases. Hence, in the thermoelectric conversion material represented by the compound formula (2′), x and y are set to be 30≦x≦35 and 30≦y≦35, respectively. In addition, x and y are more preferably set to be 33≦x≦34 and 33≦y≦34, respectively.

The thermoelectric conversion material represented by the compound formula (2′) includes at least one element selected from the group consisting of C, N and O. The thermal conductivity κ of the thermoelectric conversion material represented by the compound formula (2′) is remarkably decreased by the at least one element selected from the group consisting of C, N and O, and hence, the thermoelectric conversion efficiency is improved.

In addition, in the thermoelectric conversion material represented by the compound formula (2′), the composition ratio p of at least one element selected from the group consisting of C, N and O is set to be 0.05<p. Hence, when the thermoelectric conversion material represented by the compound formula (2′) is produced, the accurate control of the composition ratio P is not necessary. Since C, N and O are generally liable to be included as impurities in a production process of a thermoelectric conversion material, the accurate control at a low composition ratio is difficult. Hence, when it is not necessary to accurately control the composition ratio p with a strict upper limit, it is very advantageous in terms of productivity.

Accordingly, although the thermoelectric conversion material represented by the compound formula (2′) is a harmless and non-toxic material, the effect of improving the thermoelectric conversion efficiency can be obtained by at least one element selected from the group consisting of C, N and O, and in addition, production can be performed with good productivity.

A further embodiment of the thermoelectric conversion material according to the present invention will be described hereunder.

The inventors of the present invention further intensively investigated rare earth elements having an atomic radius larger than that of any one of Ti, Zr and Hf.

It was discovered that also in a thermoelectric conversion material in which M of a half Heusler compound MNiSn (in which M=Ti, Zr and Hf) is partly replaced with at least one element selected from the group consisting of Y and rare earth elements, when at least one element selected from the group consisting of C, N and O is included, the thermal conductivity κ can be remarkably improved, and a high ZT value can be obtained.

That is, as represented by the following compound formula (3′), the thermoelectric conversion material according to this embodiment includes at least one element selected from the group consisting of C, N and O.
((Ln_{d}(Tiₐ₂Zr_{b2}Hf_{c2})_{1-d})ₓNi_{y}Sn_{100-x-y})₁₋ₚAₚ (3′)

In the above compound formula (3′), the element A is at least one element selected from the group consisting of C, N and O; element Ln is at least one element selected from the group consisting of Y and rare earth elements; 0≦a2≦1, 0≦b2≦1, 0≦c2≦1, and a2+b2+c2=1 hold; 0<d≦0.3 holds; 30≦x≦35 and 30≦y≦35 hold; and p>0.05 holds.

When the element M of half Heusler compound MNiSn (in which M=Ti, Zr and Hf) is partly replaced with at least one element selected from the group consisting of Y and rare earth elements, the atomic radiuses of which are larger than any of Ti, Zr and Hf, the thermal conductivity κ can be improved.

That is, the element Ln (at least one element selected from the group consisting of Y and rare earth elements) is an effective element to decrease the thermal conductivity κ of the thermoelectric conversion material.

In the element Ln, elements from La having an atomic number of 57 in the periodic table to Lu having an atomic number of 71 are all included as the rare earth elements. In addition, when the melting point and the atomic radius are taken into consideration, Er, Gd and Nd are particularly preferable as the element Ln.

The effect of decreasing the thermal conductivity κ can be obtained even by a small amount of the element Ln. However, the composition ratio d of Ln to the total of Ln, Ti, Zr and Hf is preferably set to 0.1 atomic percent or more. When the composition ratio d of the element Ln is more than 30 atomic percent, a crystal phase, such as an LnSn₃ phase, other than the MgAgAs type crystal phase apparently precipitates, and as a result, the Seebeck coefficient α may be decreased in some cases.

Hence, the composition ratio d is preferably set to be 0<d≦0.3 and is more preferably set to be 0.001≦d≦0.3.

In addition, also in a thermoelectric conversion material in which the element M of the half Heusler compound MNiSn (in which M=Ti, Zr and Hf) is partly replaced with Ln, when at least one element selected from the group consisting of C, N and O is included, the thermal conductivity κ is remarkably decreased, and hence, the thermoelectric conversion efficiency can be improved.

When at least one element selected from the group consisting of C, N and O is included in a thermoelectric conversion material in which the element M of the half Heusler compound MNiSn (in which M=Ti, Zr and Hf) is replaced with Ln, this thermoelectric conversion material has a composition represented by the compound formula (3′).

In the case described above, when the composition ratio p of at least one element selected from the group consisting of C, N and O is allowed so that p>0.05 holds, the composition ratios p of C, N and O, which are liable to be included as impurities in a production process, are not necessary to be accurately controlled, and hence, the productivity of the thermoelectric conversion material can be improved.

By the presence of Ln, the same effect as that obtained in the compound formula (2′), which decreases the thermal conductivity κ by including all Ti, Zr and Hf, can be achieved. Hence, in the compound formula (3′), Ti, Zr and Hf are not necessarily present at the same time. Accordingly, as for a2, b2, and c2, 0≦a2≦1, 0≦b2≦1, 0≦c2≦1, and a2+b2+c2=1 hold.

Further, in the compound formula (3′), in order to have a phase having an MgAgAs type crystal structure at a high volume fraction and to obtain a high Seebeck coefficient, x and y are set to be 30≦x≦35 and 30≦y≦35, respectively.

In general, in a half Heusler compound, when the total number of valence electrons is approximately 18, a high Seebeck coefficient can be observed. For example, the outer-shell electron arrangement of ZrNiSn is represented by Zr(5d²6s²), Ni(3d⁸4s²) and Sn(5s²5p²), and hence, the total number of valence electrons is 18. The total number of valence electrons of TiNiSn and HfNiSn also is 18 as is the case described above.

On the other hand, when at least one of Ti, Zr and Hf is partly replaced with a rare earth element as represented by the compound formula (3′), since a rare earth element other than Ce, Eu and Yb has an outer-shell electron arrangement represented by (5d¹6s²) and hence is trivalent in many cases, the total number of valence electrons may be deviated from 18 in some cases.

However, the deviation of the total number of valence electrons can be appropriately corrected by adjustment of x and y.

Besides the same effect as that of the thermoelectric conversion material represented by the compound formula (2′), the thermoelectric conversion material represented by the compound formula (3′) can further decrease the thermal conductivity κ as compared to that of the thermoelectric conversion material represented by the compound formula (2′) by partly replacing M of the half Heusler compound MNiSn (M=Ti, Zr and Hf) with at least one element selected from the group consisting of Y and the rare earth elements.

In the compound formulas (2′) and (3′), Ti, Zr, and Hf may be partly replaced with at least one element selected from the group consisting of V, Nb, Ta, Cr, Mo and W. The elements mentioned above may be used alone or in combination to partly replace Ti, Zr and Hf.

By this replacement, the total number of valence electrons in the MgAgAs type crystal phase can be adjusted, and as a result, the Seebeck coefficient α can be increased and/or the electrical resistivity ρ can be decreased.

However, the amount used for the replacement is preferably set to 30 atomic percent or less of the total amount of Ti, Zr and Hf. When the amount used for the replacement is more than 30 atomic percent, a phase other than the MgAgAs type crystal phase apparently precipitates, and as a result, the Seebeck coefficient α may be deceased in some cases.

In addition, Ni in the compound formulas (2′) and (3′) may be partly replaced with at least one element selected from the group consisting of Mn, Fe, Co and Cu. The elements mentioned above may be used alone or in combination to partly replace Ni.

By this replacement, for example, the total number of valence electrons in the MgAgAs type crystal phase can be adjusted, and as a result, the Seebeck coefficient α can be increased and/or the electrical resistivity ρ can be decreased.

However, the amount used for the replacement is preferably set to 50 atomic percent or less of the amount of Ni. In particular, in the case in which Cu is used for the replacement, when the amount thereof used for the replacement is excessive, the growth of the MgAgAs type crystal phase may be inhibited in some cases, and hence, the amount for the replacement is preferably set to 30 atomic percent or less of the amount of Ni.

In addition, Sn in the compound formulas (2′) and (3′) may be partly replaced with at least one element selected from the group consisting of Si, Mg, As, Sb, Bi, Ge, Pb, Ga and In. The elements mentioned above may be used alone or in combination to partly replace Sn.

By this replacement, for example, the total number of valence electrons in the MgAgAs type crystal phase can be adjusted, and as a result, the Seebeck coefficient α can be increased and/or the electrical resistivity ρ can be decreased.

However, in consideration of harmfulness, toxicity and material cost of an element used for the replacement of Sn, the elements of Si, Sb and Bi are particularly preferable. In addition, the amount used for the replacement is preferably set to 30 atomic percent or less of the amount of Sn. When the amount used for the replacement is more than 30 atomic percent, a phase other than the MgAgAs type crystal phase apparently precipitates, and as a result, the Seebeck coefficient α may be deceased in some cases.

Next, a method for producing the thermoelectric conversion material according to the present invention will be described.

First, an alloy containing predetermined amounts of elements shown in the compound formula (2′) or (3′) is formed, for example, by arc melting or high-frequency melting. When the alloy is formed, for example, a liquid quenching method, such as a single roll method, a twin roll method, a rotary disc method, or a gas atomizing method, or a method using solid phase reaction, such as a mechanical alloying method, may be used.

Whenever necessary, heat treatment may be performed for the alloy thus formed. By this heat treatment, formation of a phase other than the MgAgAs type crystal phase can be suppressed, and/or the crystal grain diameter can be controlled. However, when the heat treatment is performed at a high temperature, the average crystal grain diameter of the MgAgAs type crystal phase may be increased, and as a result, the thermoelectric properties may be degraded in some cases. Thus, the temperature for the heat treatment is preferably set to less than 1,200° C. Then, after the alloy is pulverized by a ball mill, a brown mill, a stamp mill or the like, a powdered alloy thus obtained is integrally molded by a hot press method, a discharge plasma sintering method or the like.

In order to prevent oxidation of the alloy, in general, steps, such as melting, liquid quenching, mechanical alloying, heat treatment, pulverization and integral molding steps, are performed in an inert gas atmosphere containing Ar or the like.

In addition, in the present invention, in order to forcedly include at least one element selected from the group consisting of C, N and O in a thermoelectric conversion material, the concentrations of C, N and O in an atmospheric gas are controlled, so that the above elements are included in the material.

Alternatively, as is the case in the past, after an alloy is formed in an inert atmosphere, this alloy may be heat-treated in an atmosphere of a gas containing C, N and O, or a compound gas thereof, such as a nitrogen gas, an oxygen gas, a methane gas or an ammonia gas, so that C, N, and O is included in the thermoelectric conversion material.

In addition, in an alloy melting step, when a high-frequency induction melting method using a crucible is employed, the elements described above may be included in the thermoelectric conversion material from a crucible material such as alumina, zirconia, or magnesia.

Furthermore, after the pulverization step, in order to adsorb N and O on powder surfaces, heating may be performed at a temperature of approximately 100° C. to 300° C. for approximately 0.5 to 100 hours in the atmosphere.

Next, the obtained molded body is machined to have a desired dimension, and thus, the thermoelectric conversion material of the present invention is obtained. The shape and the dimension of the molded body may be optionally selected. For example, there may be mentioned a cylindrical shape having an outer diameter of 0.5 to 10 mm and a thickness of 1 to 30 mm or a rectangular parallelepiped approximately having a square of 0.5 to 10 mm by 0.5 to 10 mm and a thickness of 1 to 30 mm.

Next, a further embodiment of a thermoelectric conversion device using the thermoelectric conversion material of the present invention will be described with reference to FIGS. 1 and 3.

A thermoelectric conversion device of this embodiment has substantially the same structure as that shown in FIG. 1.

That is, the thermoelectric conversion device 10 has the structure which comprises p-type elements 1 each containing a thermoelectric conversion material (p-type thermoelectric conversion material) made of a p-type semiconductor, n-type elements 2 each containing a thermoelectric conversion material (n-type thermoelectric conversion material) made of an n-type semiconductor, electrodes 3 which alternately connects the p-type elements 1 and the n-type elements 2, and insulating substrates 4 covering the electrodes 3.

The p-type elements 1 and the n-type elements 2 are alternately connected to each other via the electrodes 3, so that pn semiconductor pairs are formed.

FIG. 3 is an enlarged view showing one of the pn semiconductor pairs of the thermoelectric conversion device 10′ shown in FIG. 1.

For example, the case is assumed in which a temperature gradient is formed between insulating substrates 4a and 4b by maintaining the insulating substrates 4a and 4b at a low temperature and a high temperature, respectively.

In this case, in the p-type element 1, holes 5 having a positive charge are moved to an electrode 3a at a high temperature side. Hence, in the p-type element 1, the electrode 3a at a high temperature side has a high potential as compared to an electrode 3b at a low temperature side.

On the other hand, in the n-type element 2, electrons 6 having a negative charge are moved to the electrode 3b at a low temperature side. Hence, in the n-type element 2, the electrode 3b at a low temperature side has a high potential as compared with that of an electrode 3c at a high temperature side.

As a result, the potential difference is generated between the electrodes 3a and 3c. The electrode 3a functions as a positive electrode, and the electrode 3b functions as a negative electrode.

The thermoelectric conversion device 10′ can obtain a high voltage as compared to that of the structure shown in FIG. 3 since the pn semiconductor pairs are connected in series as shown in FIG. 1, and as a result, a larger electrical power can be ensured.

In this thermoelectric conversion device 10′, either one of both of the p-type elements 1 and the n-type elements 2 are formed from the thermoelectric conversion material represented by the compound formula (2′) or (3′) according to the present invention. When only the p-type elements 1 or the n-type elements 2 are formed using the thermoelectric material according to the present invention, the other type of elements are formed using a Bi—Te-based or a Pb—Te-based thermoelectric material.

Accordingly, the thermoelectric conversion device 10′ can be formed from a harmless and non-toxic thermoelectric conversion material, can use an effect of improving the thermoelectric conversion efficiency of this thermoelectric conversion material by at least one element selected from the group consisting of C, N and O, and can be produced with good productivity.

### EXAMPLES

The thermoelectric conversion material according to the present invention will be described in detail with reference to examples.

Table 1′ is a table in which the properties of Example 1 and Comparative Examples 1 to 3 are shown for the comparison purpose.

After predetermined raw materials were selected from Er, Ta, Ti, Zr, Hf, Ni, Sn, Sb and C and were weighed, followed by high-frequency melting using a magnesium crucible, an alloy was formed by casing molten raw materials in a casting mold. Next, the alloy thus formed was pulverized to a size of 45 μm or less using a mortar, and in the example and comparative examples, which included N or O, in order to adsorb N or O on powder surfaces, a heat treatment was performed at 120° C. for 1 hour in the atmosphere. Subsequently, hot press was performed, and hence a molded body having an outer diameter of 20 mm and a thickness of 3 mm was obtained. The hot press was performed by the steps of increasing the temperature to 1,200° C. at a rate of 15° C./minute in a vacuum atmosphere, holding this temperature for 1 hour, and then decreasing the temperature to room temperature. The molded body thus processed was machined to have a desired shape and was then used for evaluation of the thermoelectric properties.

Remaining parts of the thermoelectric conversion material after the machining were used for evaluation of a produced phase and the composition thereof by a powder x-ray diffraction and an ICP emission spectroscopic analysis, and as a result, it was confirmed that an MgAgAs type single crystal phase is substantially present in all the samples. The compositions obtained by this analysis are shown in Table 1′.

In addition, the thermal diffusivity, the density, and the specific heat of the molded body were measured by a laser flash method, the Archimedes method, and a DSC (differential scanning calorimeter) method, respectively, and from the results obtained therefrom, the thermal conductivity κ was obtained. Furthermore, after the molded body was cut into a needle shape, the Seebeck coefficient α was measured. Furthermore, this needle-shaped molded body was used for measurement of the electrical resistivity ρ using a four terminal method. The performance indexes ZT (Z=α²/ρκ) at 700K obtained from the Seebeck coefficient α, the electrical resistivity ρ, and the thermal conductivity κ are shown in Table 1′.

TABLE 1′

| | | Performance |
|---|---|---|
| | | Index ZT |
| | Analyzed Composition (Atomic percent) | (700K) |
| Example 1 | ((Er_{0.05}(Ti_{0.34}Zr_{0.33}Hf_{0.33})_{0.95})₃₄Ni₃₃(Sn_{0.985}Sb_{0.015})₃₃)_{0.984}O_{0.052} | 1.24 |
| Comparative | ((Er_{0.05}(Ti_{0.34}Zr_{0.33}Hf_{0.33})_{0.95})₃₄Ni₃₃(Sn_{0.985}Sb_{0.015})₃₃)_{0.984}O_{0.0012} | 1.55 |
| Example 1 | | |
| Comparative | ((Er_{0.05}(Ti_{0.34}Zr_{0.33}Hf_{0.33)0.95)34}Ni₃₃(Sn_{0.985}Sb_{0.015)33)0.995}O_{0.005} | 1.56 |
| Example 2 | | |
| Comparative | ((Ta_{0.01}(Zr_{0.70}Hf_{0.80})_{0.99})₃₅Ni₃₄Sn₃₁)_{0.981}O_{0.015}N_{0.004} | 1.18 |
| Example 3 | | |

As apparent from Table 1′, in the Comparative Examples 1 and 2 in which the composition ratio p is accurately controlled so that p≦0.5 holds, a high ZT value, such as 1.5 or more, at 700K is obtained. On the other hand, it is understood that in the Example 1 in which the composition ratio is set so that p>0.5 holds at which improvement in productivity can be expected, a sufficiently high ZT value, such as 1.24, can be obtained. In addition, it is understood that in the Comparative Example 3 in which Ti is not included in the compound formula (2′), although N and O are accurately controlled, a low ZT value as compared to that obtained in the Example 1 is only obtained.

What is claimed is:

1. A thermoelectric material which is represented by following composition formula of (Tiₐ₁Zr_{b1}Hf_{c1})ₓA_{y}B_{100-x-y}, in which element A is at least one element selected from the group consisting of Ni and Co, element B is at least one element selected from the group consisting of Sn and Sb, 0≦a1≦1, 0≦b1≦1, 0≦c1≦1, and a1+b1+c1=1 hold and 30≦x≦35 and 30≦y≦35 hold, and which comprises a phase having an MgAgAs type crystal structure as a major phase, wherein density of the thermoelectric material is more than 99.0% of true density.

2. A thermoelectric material which is represented by the following composition formula of (Ln_{d}(Tiₐ₂Zr_{b2}Hf_{c2})_{1-d})ₓA_{y}B_{100-x-y}, in which element Ln is at least one element selected from the group consisting of Y and rare earth elements, element A is at least one element selected from the group consisting of Ni and Co, element B is at least one element selected from the group consisting of Sn and Sb, 0≦a2≦1, 0≦b2≦1, 0≦c2≦1, and a2+b2+c2=1 hold, 0<d≦0.3 holds and 30≦x≦35 and 30≦y≦35 hold, and which comprises a phase having an MgAgAs type crystal structure as a major phase, wherein the density of the thermoelectric material is more than 99.0% of the true density.

3. A thermoelectric conversion material which is represented by the following composition formula of (Tiₐ₁Zr_{b1}Hf_{c1})ₓNi_{y}Sn_{100-x-y})₁₋ₚAₚ, in which element A is at least one element selected from the group consisting of C, N, and O, 0<a1<1, 0<b1<1, 0<c1<1, and a1+b1+c1=1 hold, 30≦x≦35 and 30≦y≦35 hold, and 0.05<p<0.1 holds, and which comprises a phase having an MgAgAs type crystal structure as a major phase.

4. A thermoelectric conversion material which is represented by the following composition formula of ((Ln_{d}(Tiₐ₂Zr_{b2}Hf_{c2})_{1-d})ₓNi_{y}Sn_{100-x-y})₁₋ₚAₚ, in which element A is at least one element selected from the group consisting of C, N, and O, element Ln is at least one element selected from the group consisting of Y and rare earth elements, 0≦a2≦1, 0≦b2≦1, 0≦c2≦1, and a2+b2+c2=1 hold, 0<d≦0.3 holds, 30≦x≦35 and 30≦y≦35 hold, and 0.05<p<0.1 holds, and which comprises a phase having an MgAgAs type crystal structure as a major phase.

5. The thermoelectric material according to any one of claims 1 to 4, wherein at least one of the Ti, Zr and Hf is partly replaced with at least one element selected from the group consisting of V, Nb, Ta, Cr, Mo and W.

6. The thermoelectric material according to any one of claims 1 to 4, wherein the element A is partly replaced with at least one element selected from the group consisting of Mn, Fe and Cu.

7. The thermoelectric material according to any one of claims 1 to 4, wherein the element B is partly replaced with at least one element selected from the group consisting of Si, Mg, As, Bi, Ge, Pb, Ga and In.

8. A thermoelectric conversion device comprising:
at least one p-type element including a p-type thermoelectric material; and
at least one n-type element including an n-type thermoelectric material, the p-type element and the n-type element being alternately connected to each other in series,
wherein at least one of the p-type thermoelectric material and the n-type thermoelectric material is represented by the following composition formula of (Tiₐ₁Zr_{b1}Hf_{c1})ₓA_{y}B_{100-x-y}, in which element A is at least one element selected from the group consisting of Ni and Co, element B is at least one element selected from the group consisting of Sn and Sb, 0≦a1≦1, 0≦b1≦1, 0≦c1≦1, and a1+b1+c1=1 hold and 30≦x≦35 and 30≦y≦35 hold, and at least one of the p-type and n-type thermoelectric materials comprises a phase having an MgAgAs type crystal structure as a major phase, wherein density of the thermoelectric material is more than 99.0% of true density.

9. A thermoelectric conversion device comprising:
at least one p-type element including a p-type thermoelectric material; and
at least one n-type element including an n-type thermoelectric material, the p-type element and the n-type element being alternately connected to each other in series,
wherein at least one of the p-type thermoelectric material and the n-type thermoelectric material is represented by the following composition formula of (Ln_{d}(Tiₐ₂Zr_{b2}Hf_{c2})_{1-d})ₓA_{y}B_{100-x-y}, in which element Ln is at least one element selected from the group consisting of Y and rare earth elements, element A is at least one element selected from the group consisting of Ni and Co, element B is at least one element selected from the group consisting of Sn and Sb, 0≦a2≦1, 0≦b2≦1, 0≦c2≦1, and a2+b2+c2=1 hold, 0<d≦0.3 holds and 30≦x≦35 and 30≦y≦35 hold, and at least one of the p-type and n-type thermoelectric materials comprises a phase having an MgAgAs type crystal structure as a major phase, wherein density of the thermoelectric material is more than 99.0% of true density.

10. A thermoelectric conversion device comprising:
at least one p-type element including a p-type thermoelectric conversion material; and
at least one n-type element including an n-type thermoelectric conversion material, the p-type element and the n-type element being alternately connected to each other in series,
wherein at least one of the p-type thermoelectric conversion material and the n-type thermoelectric conversion material is represented by the following composition formula of (Tiₐ₁Zr_{b1}Hf_{c1})ₓNi_{y}Sn_{100-x-y}, in which element A is at least one element selected from the group consisting of C, N, and O, 0<a1<1, 0<b1<1, 0<c1<1, and a1+b1+c1=1 hold, 30≦x≦35 and 30≦y≦35 hold, and 0.05<p<0.1 holds, and at least one of the p-type and n-type thermoelectric materials comprises a phase having an MgAgAs type crystal structure as a major phase.

11. A thermoelectric conversion device comprising:
at least one p-type element including a p-type thermoelectric conversion material; and
at least one n-type element including an n-type thermoelectric conversion material, the p-type element and the n-type element being alternately connected to each other in series,
wherein at least one of the p-type thermoelectric conversion material and the n-type thermoelectric conversion material is represented by the following composition formula of ((Ln_{d}(Tiₐ₂Zr_{b2}Hf_{c2})_{1-d})ₓNi_{y}Sn_{100-x-y})₁₋ₚAₚ, in which element A is at least one element selected from the group consisting of C, N, and O, element Ln is at least one element selected from the group consisting of Y and rare earth elements, 0≦a2≦1, 0≦b2≦1, 0≦c2≦1, and a2+b2+c2=1 hold, 0<d≦0.3 holds, 30≦x≦35 and 30≦y≦35 hold, and 0.05<p<0.1 holds, and at least one of the p-type and n-type thermoelectric materials comprises a phase having an MgAgAs type crystal structure as a major phase.

12. The thermoelectric conversion device according to any one of claims 8 to 12, wherein at least one of the Ti, Zr and Hf is partly replaced with at least one element selected from the group consisting of V, Nb, Ta, Cr, Mo and W.

13. The thermoelectric conversion device according to any one of claims 8 to 12, wherein the element A is partly replaced with at least one element selected from the group consisting of Mn, Fe and Cu.

14. The thermoelectric conversion device according to claim any one of claims 8 to 12, wherein the element B is partly replaced with at least one element selected from the group consisting of Si, Mg, As, Bi, Ge, Pb, Ga and In.
